(19) United States
(12) Patent Application Publication
(10) Pub. No.: US 2014/0209243 A1
(43) Pub. Date: Jul. 31, 2014

(54) Plasma Equipment and Method of Dry-Cleaning the Same

(71) Applicant: Samsung Electronics Co., Ltd., Gyeonggi-do (KR)

(72) Inventors: Se-Yeon Kim, Hwaseong-si (KR); Kyung Hwan Jeong, Hwaseong-si (KR)

(73) Assignee: Samsung Electronics Co., Ltd., Gyeonggi-do (KR)

(21) Appl. No.: 14/163,208

(22) Filed: Jan. 24, 2014

(30) Foreign Application Priority Data
Jan. 25, 2013 (KR) 10-2013-0008697

(51) Int. Cl. H01J 37/32

(52) U.S. Cl. CPC H01J 37/32009
USPC 156/345.34

(57) ABSTRACT

A plasma equipment includes a chamber, a shower head disposed in an upper part of an inner space of the chamber for discharging a cleaning gas into the chamber, a plasma generator for generating a plasma gas from the cleaning gas, a lower electrode disposed in a lower part of the inner space of the chamber, a chuck covering the lower electrode, and a field inducing unit disposed outside the chamber for inducing an electric field or a magnetic field within the chamber in a direction parallel to top surfaces of the chuck and the lower electrode. The field inducing unit concentrates the plasma gas on an inner sidewall of the chamber and protects the chuck from the plasma gas.

### CROSS-REFERENCE TO RELATED APPLICATIONS

This U.S. non-provisional patent application claims priority under 35 U.S.C. §119 to Korean Patent Application No. 10-2013-0008697, filed on Jan. 25, 2013, which is incorporated by reference herein in its entirety.

### FIELD

The inventive concept relates to semiconductor manufacturing equipment and methods of cleaning the same and, more particularly, to plasma equipment and methods of dry-cleaning the same.

### BACKGROUND

Generally, semiconductor devices are formed by a plurality of unit processes including a deposition process of a thin layer and an etching process. The etching process is performed using a capacitively coupled plasma (CCP) reaction. The CCP reaction means that an etching reaction gas is excited in a plasma state by a high frequency power. The etching reaction gas may include a strong acid gas. The strong acid gas may etch a silicon-based layer or a silicon-based substrate. For improving confidence of the etching process, an inner surface of a chamber of a plasma equipment is treated with a silicon ingredient of the same quality as an etch target material.

A contamination material of a polymer ingredient may be caused in the etching process. The contamination material may mainly occur on a part of a sidewall of the chamber. The partial contamination material may cause process errors. The contamination material may be removed by a cleaning gas such as an oxygen (O₂) gas. The oxygen gas may have reactivity lower than that of the strong acid gas. Since the strong acid gas may damage a chuck, a dry or wet cleaning process using the strong acid gas is not performed in most of etching equipments.

### SUMMARY

Embodiments of the inventive concept may provide plasma equipment capable of using a strong acid-cleaning gas in a capacitively coupled plasma reaction and methods of dry-cleaning the same.

Embodiments of the inventive concept may also provide plasma equipment capable of locally cleaning the inside of a chamber and methods of dry-cleaning the same.

Embodiments of the inventive concept may further provide plasma equipment capable of minimizing or preventing damage of a chuck and methods of dry-cleaning the same.

In one aspect, a plasma equipment may include: a chamber having an inner space; a shower head disposed in an upper part of the inner space of the chamber, the shower head configured to discharge a cleaning gas into the chamber; a plasma generator configured to generate a plasma gas from the cleaning gas; a lower electrode disposed in a lower part of the inner space of the chamber; a chuck on the lower electrode; and a field inducing unit disposed outside the chamber and configured to induce an electric field or a magnetic field within the chamber in a direction parallel to top surfaces of the chuck and the lower electrode to concentrate the plasma gas on an inner sidewall of the chamber and to protect the chuck from the plasma gas .

In some embodiments, the field inducing unit may include field inducing first and second electrodes disposed opposite to each other on an outer sidewall of the chamber; and the field inducing electrodes may induce the electric field in the chamber. The field inducing electrodes may be rotatable along the outer sidewall of the chamber and may be movable vertically along the outer sidewall of the chamber.

In some embodiments, the chamber may include ceramic, polymer, glass, or plastic.

In some embodiments, the field inducing unit may include a field inducing coil wrapped around the chamber that induces the magnetic field in the chamber; and the field inducing coil may have a center axis extending in a direction from one side to another, opposed side of the chamber. The center axis may be parallel to or coincide with a direction of the magnetic field.

In some embodiments, the chamber may include an inner chamber and an outer chamber surrounding the inner chamber. The inner chamber and the outer chamber may be configured to rotate relative to each other and to move vertically relative to each other. A height of the outer chamber may be two or more times greater than a height of the inner chamber. The outer chamber may have a hexahedral shape or a cylindrical shape. The inner chamber may have a cylindrical shape.

In some embodiments, the plasma generator may include an upper electrode disposed in the shower head in the upper part of the inner space of the chamber.

In another aspect, a method of dry-cleaning a plasma equipment may include: pumping air in a chamber; inducing a plasma reaction in the chamber; generating an electric field or a magnetic field in a direction parallel to a top surface of a chuck disposed on a bottom of the chamber; and supplying a cleaning gas including fluorine into the chamber.

In some embodiments, pumping the air may further include: providing an inert gas into the chamber.

In some embodiments, the method may further include: interrupting the supplying of the cleaning gas; removing the electric field or the magnetic field in the chamber; and interrupting the plasma reaction.

In another aspect, a plasma equipment includes a chamber including an inner chamber and an outer chamber. The inner chamber has an inner space and the outer chamber surrounds the inner chamber. A shower head is disposed in an upper part of the inner space of the inner chamber, with the shower head configured to discharge a cleaning gas into the inner chamber. A plasma generator is disposed in the inner space of the inner chamber, with the plasma generator configured to generate a plasma gas from the cleaning gas. A lower electrode is disposed in a lower part of the inner space of the inner chamber and a chuck is on the lower electrode. A field inducing unit is disposed outside the inner chamber, with the field inducing unit configured to induce an electric field and/or a magnetic field within the inner chamber in a direction parallel to top surfaces of the chuck and the lower electrode to concentrate the plasma gas on an inner sidewall of the inner chamber and to protect the chuck from the plasma gas. The inner chamber and the field inducing unit are movable relative to one another such that the plasma gas is concentrated on different areas of the inner sidewall of the inner chamber.

In some embodiments, the field inducing unit includes first and second field inducing electrodes disposed opposite to each other on an outer sidewall of the inner chamber, wherein the field inducing electrodes induce the electric field in the inner chamber. The first and second field inducing electrodes may be movable vertically together along the outer sidewall of the inner chamber. The first and second field inducing electrodes may be rotatable together along the outer sidewall of the inner chamber.

In some embodiments, the field inducing unit includes a field inducing coil helically disposed around the outer chamber, wherein the field inducing coil induces the magnetic field in the inner chamber. The inner chamber may be rotatable within the outer chamber. The outer chamber may be rotatable about the inner chamber. The inner and outer chambers may be movable vertically relative to one another. The inner chamber may be movable vertically within the outer chamber.

In some embodiments, the field inducing unit includes: first and second field inducing electrodes disposed opposite to each other on an outer sidewall of the inner chamber, wherein the field inducing electrodes induce the electric field in the inner chamber; and a field inducing coil disposed around the outer chamber, wherein the field inducing coil induces the magnetic field in the inner chamber.

### BRIEF DESCRIPTION OF THE DRAWINGS

The inventive concept will become more apparent in view of the attached drawings and accompanying detailed description.

FIG. 1 is a cross-sectional view illustrating a plasma equipment according to a first embodiment of the inventive concept;

FIG. 2 is a plan view of the plasma equipment of FIG. 1;

FIG. 3 is a cross-sectional view illustrating a plasma equipment according to a second embodiment of the inventive concept;

FIG. 4 is a plan view of the plasma equipment of FIG. 3;

FIG. 5 is a cross-sectional view illustrating a plasma equipment according to an application example of the inventive concept;

FIG. 6 is a plan view of the plasma equipment of FIG. 5; and

FIG. 7 is a flowchart illustrating a method of dry-cleaning a plasma equipment according to embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and may be exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, embodiments in the detailed description will be described with sectional and/or plan views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third, etc. may be used herein to describe various elements, these elements should not be limited by these terms. These terms are only used to distinguish one element from another element. Thus, a first element in some embodiments could be termed a second element in other embodiments without departing from the teachings of the present inventive concept. Exemplary embodiments of aspects of the present inventive concept explained and illustrated herein include their complementary counterparts. The same reference numerals or the same reference designators denote the same elements throughout the specification.

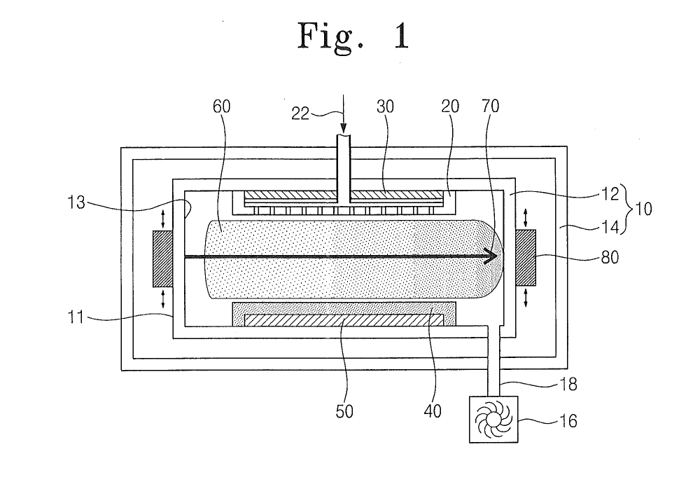

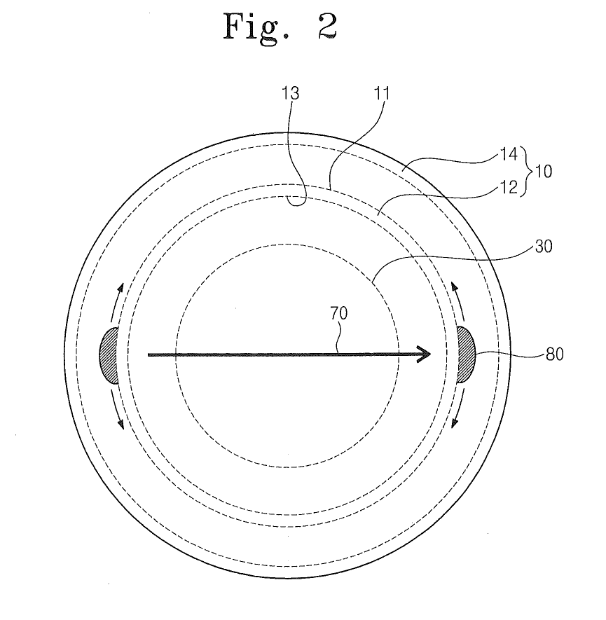

FIG. 1 is a cross-sectional view illustrating a plasma equipment according to a first embodiment of the inventive concept. FIG. 2 is a plan view of the plasma equipment of FIG. 1.

Referring to FIGS. 1 and 2, a plasma equipment may include a chamber 10, a shower head 20, an upper electrode 30, a chuck 40, a lower electrode 50, and a plurality of field inducing electrodes 80.

The chamber 10 may have an inner space separated from the outside of the chamber 10. The chamber 10 may include an inner chamber 12 and an outer chamber 14. Each of the inner and outer chambers 12 and 14 may have a cylindrical shape. The inner chamber 12 may be disposed in the outer chamber 14. The inner chamber 12 may be formed of a non-metallic material such as ceramic, polymer, glass, or plastic. The outer chamber 14 may include a metal such as SUS (e.g., stainless steel) or iron. A vacuum pump 16 may pump air disposed in the inner chamber 12. The inner chamber 12 may be in a low-vacuum state having a pressure lower than the atmospheric pressure. A pumping pipe 18 may be connected to a bottom of the inner chamber 12.

The shower head 20 may provide a reaction gas 22 into the inner chamber 12. The reaction gas 22 may include a strong acid-reaction gas such as SF₆ or C₂F₄. The strong acid-reaction gas 22 may etch silicon-based materials. The shower head 20 may be disposed in an upper part of the inner chamber 12. The reaction gas 22 may flow from the top to the bottom of the inner chamber 12.

The upper electrode 30 may be disposed in the shower head 20. The shower head 20 may protect the upper electrode 30 from the reaction gas 22. The upper electrode 30 may be disposed on an inner top surface of the inner chamber 12. The upper electrode 30 may provide a high frequency power to the reaction gas 22. The high frequency power may be supplied from an external power voltage supply part (not shown) and an external matching box, The reaction gas 22 may be excited in a plasma state by the high frequency power.

The chuck 40 may be disposed in a lower region of the inner chamber 12. The chuck 40 may fix a substrate on a bottom or a bottom portion of the chamber 10. The substrate may be fixed on the chuck 40 by electrostatic force. The chuck 40 may be formed of a silicon material or a ceramic (Al₂O₃) material. The lower electrode 50 may be disposed in the chuck 40. The chuck 40 may cover the lower electrode 50. The lower electrode 50 may be protected from the reaction gas 22 by the chuck 40.

The lower electrode 50 and the upper electrode 30 may be disposed parallel to each other in the inner chamber 12. The lower electrode 50 may be connected to the power voltage supply part. The upper electrode 30 may be an anode and the lower electrode 50 may be a cathode. A capacitance may be induced between the upper electrode 30 and the lower electrode 50. The lower electrode 50 may be applied with a high frequency power having a voltage lower than that of the high frequency power applied to the upper electrode 30. The reaction gas 22 may be accelerated by the high frequency power. The accelerated reaction gas 22 may be ionized by collisions and may generate secondary electrons. Electron avalanche may occur, and then the reaction gas 22 may be excited in the plasma state after avalanche breakdown. Here, the reaction gas 22 of the plasma state is defined as a plasma gas 60. The upper electrode 30 may correspond to a plasma generator generating the plasma gas 60 from the reaction gas 22.

The plasma gas 60 may be charged with a strong positive charge. The lower electrode 50 and the upper electrode 30 may induce a capacitively coupled plasma (CCP) reaction. The plasma equipment according to the first embodiment of the inventive concept may include a CCP type etching equipment. The plasma equipment may be used as the CCP type etching equipment. However, the inventive concept is not limited thereto. The plasma equipment according to the inventive concept may be realized as an inductively coupled plasma (ICP) type or remote plasma type etching equipment or an ICP type or remote plasma type deposition equipment.

The plasma gas 60 may be concentrated on a first inner sidewall 13 of the inner chamber 12 along an electric field 70 between the field inducing electrodes 80. The field inducing electrodes 80 may be opposite to each other on an outer sidewall 11 of the inner chamber 12. A direct current (DC) voltage or an alternating current (AC) voltage may be applied to the field inducing electrodes 80. The electric field 70 may be induced in the inner chamber 12 between the field inducing electrodes 80. The electric field 70 may be induced parallel to the upper electrode 30 and the lower electrode 50. The plasma gas 60 may be moved in the inner chamber 12 by an electrostatic force of the electric field 70. The electric field 70 may be induced in one direction between the field inducing electrodes 80. The electric field 70 may pass through a center of the inner chamber 12.

The plasma gas 60 may be concentrated in the same direction as the electric field 70. As described above, the plasma gas 60 may be charged with the strong positive charge. The electric field 70 may be induced from an anode to a cathode. For example, if the DC voltage is applied, a negative voltage may be applied to one of the field inducing electrodes 80 and a positive voltage may be applied to the other of the field inducing electrodes 80. The plasma gas 60 may be concentrated on the field inducing electrode 80 applied with the negative voltage. The first inner sidewall 13 adjacent to one of the field inducing electrodes 80 may be locally cleaned by the plasma gas 60. The plasma gas 60 may flow from the shower head 20 to the chuck 40 in a downward direction by gravity and a jetting pressure. The electric field 70 may remove or reduce a down direction flow of the plasma gas 60. This is because the electrostatic force is greater (e.g., far greater) than the gravity and the jetting pressure. The field inducing electrodes 80 may be moved. The movement of the field inducing electrodes 80 may be restricted along or on the outer sidewall 11 corresponding to a region over the chuck 40. The plasma gas 60 may not be concentrated on the chuck 40 but may partially or fully clean the first inner sidewall 13. The plasma equipment according to the first embodiment of the inventive concept may minimize damage of the chuck 40 which may otherwise be caused by the strong acid plasma gas 60.

The field inducing electrodes 80 may be moved in the state that they face each other with the inner chamber 12 therebetween. The field inducing electrodes 80 may ascend or descend along the outer sidewall 11 of the inner chamber 12 in an up direction or a down direction, Additionally, the field inducing electrodes 80 may rotate around the inner chamber 12 (e.g., around the outer sidewall 11). The electric field 70 may be successively induced to a portion or an entire portion of the first inner sidewall 13. That is, the plasma gas 60 may be concentrated on different portions of the inner sidewall 13 along the direction of the electric field 70 as the electrodes 80 move relative to the outer sidewall 11 or the inner chamber 12. The plasma gas 60 may clean the portion or the entire portion of the first inner sidewall 13 along the electric field 70.

On the other hand, plasma arcing may be caused in an etching process using the CCP reaction. The plasma arcing may be caused by a contamination material (e.g., polymer) on the first inner sidewall 13. The etching process may be performed using an etching gas. The etching gas may contain the same strong acid fluorine ingredient as the cleaning gas. Here, the etching gas may also be defined as the plasma gas 60. The field inducing electrodes 80 may induce the electric field 70 in the inner chamber 12 during the etching process or immediately after the etching process, and the plasma gas 60 may be concentrated on the first inner sidewall 13 along the direction of the electric field 70. Thus, the first inner sidewall 13 of the inner chamber 12 may be cleaned by the plasma gas 60. Accordingly, the contamination material may be removed from the first inner sidewall 13 of the inner chamber 12.

As a result, the plasma equipment according to the first embodiment may provide a stable plasma process environment in the etching process,

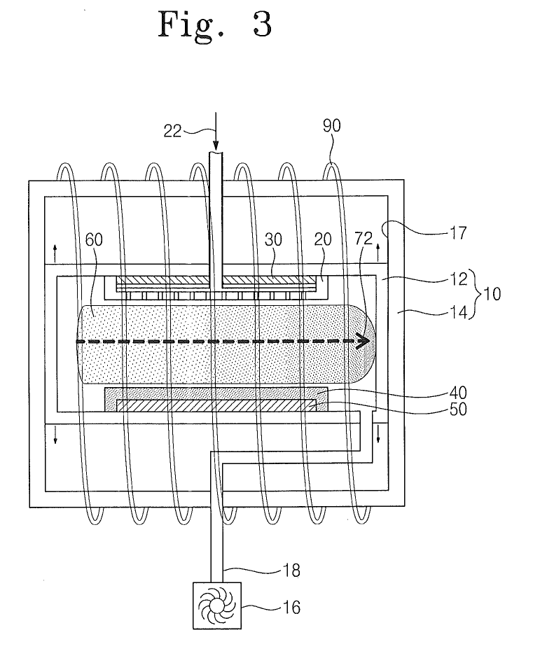

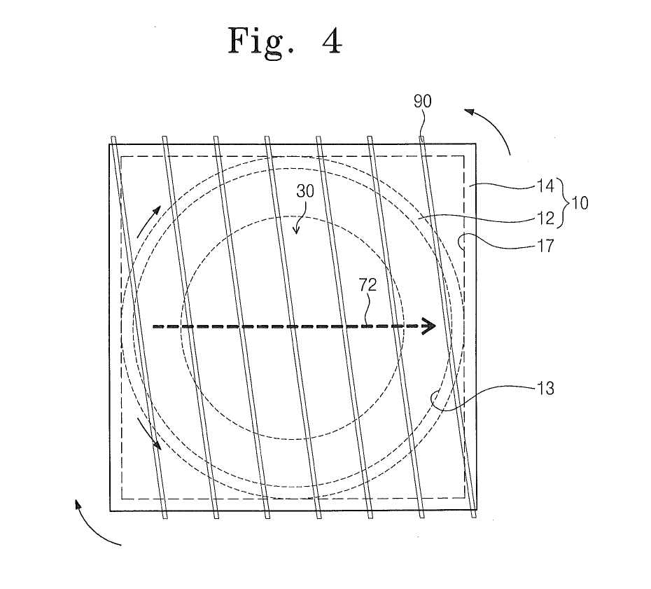

FIG. 3 is a cross-sectional view illustrating a plasma equipment according to a second embodiment of the inventive concept. FIG. 4 is a plan view of the plasma equipment of FIG. 3.

Referring to FIGS. 3 and 4, a plasma equipment may include a field inducing coil 90. The plasma equipment according to the second embodiment includes the field inducing coil 90 instead of the field inducing electrodes 80 of the first embodiment. The field inducing coil 90 may induce a magnetic field 72.

The magnetic field 72 may be induced in a chamber 10. The chamber 10 may include an inner chamber 12 and an outer chamber 14. The inner chamber 12 may be disposed in the outer chamber 14. The inner chamber 12 may have a cylindrical shape. The outer chamber 14 may have a cylindrical shape or a hexahedral shape. If the inner and outer chambers 12 and 14 have the cylindrical shapes, the chambers 12 and 14 may be disposed in different directions from each other. For example, if the inner chamber 12 is disposed in a vertical direction, the outer chamber 14 may be disposed in a horizontal direction.

The magnetic field 72 may be induced from one side to another side of the inner chamber 12. The field inducing coil 90 may be wrapped around a circumference or perimeter of the outer chamber 14. The field inducing coil 90 may be wrapped from a top to a bottom of the chamber 10. The outer chamber 14 may be a housing or a bobbin of the field inducing coil 90. A center axis of the field inducing coil 90 wrapped around the outer chamber 14 may extend from one side to another side of the outer chamber 14. In other words, the field inducing coil 90 may be repeatedly wrapped from the top to the bottom of the outer chamber 14 (e.g., the coil 90 may be helically disposed about the outer chamber 14). If a current is supplied to the field inducing coil 90, the magnetic field 72 may be induced in the field inducing coil 90. The current may be supplied by a DC voltage or an AC voltage. The AC voltage may have a low frequency of about 1 kHz to about 100 kHz. The magnetic field 72 may increase in proportion to the amplitude of the current applied to the field inducing coil 90. The magnetic field 72 may pass through the inner chamber 12 and the outer chamber 14. The center axis of the field inducing coil 90 may be parallel to or coincide with the direction of the magnetic field 72.

The magnetic field 72 may locally concentrate the plasma gas 60 on the first inner sidewall 13 of the inner chamber 12. The plasma gas 60 may clean a contamination material of the first inner sidewall 13. The magnetic field 72 may minimize damage of the chuck 40 which may otherwise be caused by the strong acid plasma gas 60. The outer chamber 14 may be fixed. The inner chamber 12 may rotate in an azimuth direction (e.g., the inner chamber 12 may rotate within the outer chamber 14). The inner chamber 12 may ascend or descend in an up or down direction within the outer chamber 14. A height of a second inner sidewall 17 of the outer chamber 14 may be two or more times greater than a height of the first inner sidewall 13 of the inner chamber 12. In other words, a height of the outer chamber 14 may be two or more times greater than a height of the inner chamber 12.

Alternatively, the inner chamber 12 may be fixed and the outer chamber 14 may rotate in the azimuth direction. The outer chamber 14 may ascend and descend relative to the inner chamber 12. The vacuum pump 16 may be disposed outside the outer chamber 14. The pumping pipe 18 may be connected between the inner chamber 12 and the vacuum pump 16. The pumping pipe 18 may be connected to the bottom of the inner chamber 12. The pumping pipe 18 may pass through a center of a bottom of the outer chamber 14. Thus, the outer chamber 14 may rotate about an axis defined by the pumping pipe 18.

In still other embodiments, the outer chamber 14 and the inner chamber 12 may be moved in opposite directions to each other, respectively. For example, the outer chamber 14 may ascend and the inner chamber 12 may descend. The magnetic field 72 may sweep along the first inner sidewall 13 of the inner chamber 12. The plasma gas 60 may partially or fully clean the first inner sidewall 13 according to the direction of the magnetic field 72.

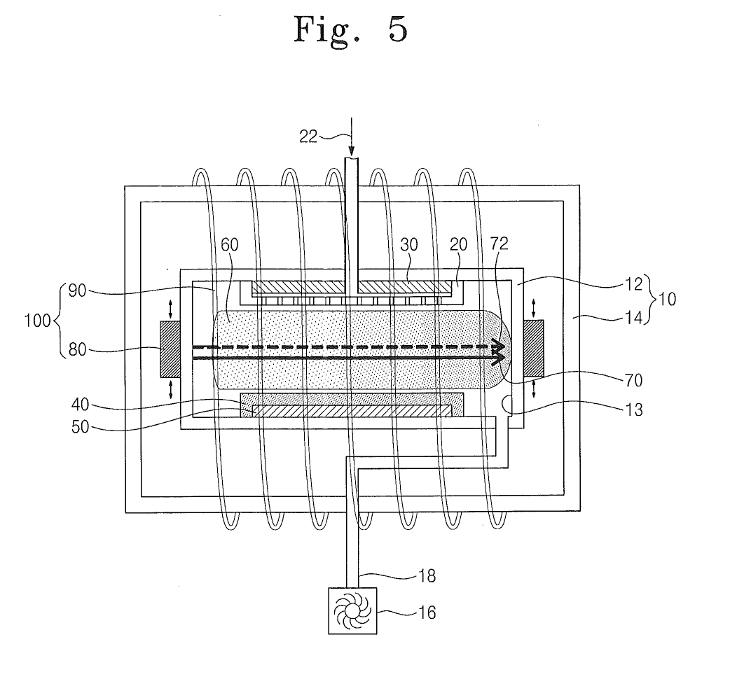

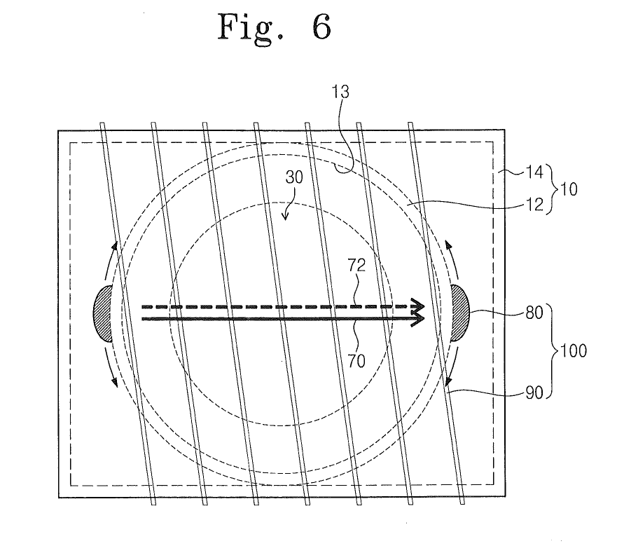

FIG. 5 is a cross-sectional view illustrating a plasma equipment according to an application example of the inventive concept. FIG. 6 is a plan view of the plasma equipment of FIG. 5.

Referring to FIGS. 5 and 6, a plasma equipment may include field inducing electrodes 80 and a field inducing coil 90 that induce an electric field 70 and a magnetic field 72 in the inner chamber 12, respectively. The plasma equipment according to the present application example may include a combined structure of the field inducing electrodes 80 and the field inducing coil 90 of the first and second embodiments. The field inducing electrodes 80 and the field inducing coil 90 may be defined as field inducing units 100. The field inducing electrodes 80 may be disposed on the outer sidewall of the inner chamber 12. The field inducing coil 90 may be wrapped around an outer circumference or perimeter of the outer chamber 14. The outer circumference or perimeter of the outer chamber 14 may include the top and the bottom of the outer chamber 14.

The plasma gas 60 may be concentrated in the directions of the electric field 70 and the magnetic field 72. The electric field 70 and the magnetic field 72 may be induced toward the first inner sidewall 13 of the inner chamber 12. If the electric field 70 and the magnetic field 72 have the same direction, the plasma gas 60 may be concentrated on one place of the first inner sidewall 13. The electric field 70 and the magnetic field 72 may sweep along the first inner sidewall 13. The plasma gas 60 may clean a portion or an entire portion of the first inner sidewall 13 according to the directions of the electric field 70 and the magnetic field 72.

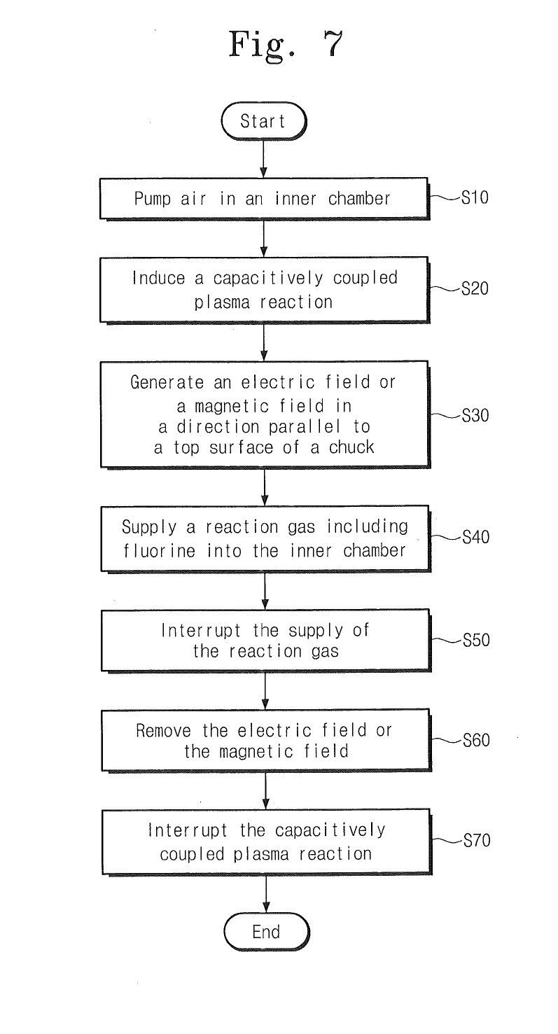

FIG. 7 is a flowchart illustrating a method of dry-cleaning a plasma equipment according to embodiments of the inventive concept.

Referring to FIGS. 1 to 7, air in the inner chamber 12 may be pumped (S10). The vacuum pump 16 may pump the air disposed in the inner chamber 12 so that a pressure in the inner chamber 12 may become about 1 mTorr. A purge gas (e.g., a nitrogen (N₂) gas) and an inert gas (e.g., an argon (Ar) gas) may be provided into the inner chamber 12.

Next, a CCP reaction of the inert gas may be induced (S20). The CCP reaction may be induced by the high frequency power. The upper electrode 30 and the lower electrode 50 may generate capacitively coupled plasma of the inert gas by the high frequency power.

Subsequently, the electric field 70 and/or the magnetic field 72 may be generated in a direction parallel to the top surface of the chuck 40 disposed on an inner bottom of the inner chamber 12 (S30). The electric field 70 and the magnetic field 72 may be induced toward the inner sidewall 13 of the inner chamber 12 by the field inducing units 80 and/or 90. The inert gas of the plasma state may be concentrated on the first inner sidewall 12 by the electric field 70 and/or the magnetic field 72.

Thereafter, a reaction gas 22 including fluorine is supplied into the inner chamber 12 (S40). The reaction gas 22 may be excited in a capacitively coupled plasma state by a high frequency power. Thus, the reaction gas 22 of the plasma state may be defined as a plasma gas 60. The plasma gas 60 may partially or fully clean the first inner sidewall 13 of the inner chamber 12. Thus, the dry-cleaning method according to embodiments of the inventive concept may use the reaction gas 22 having strong acidity in the plasma equipment inducing the capacitively coupled plasma.

If the cleaning of the first inner sidewall 13 of the inner chamber 12 is finished, an etching process of a substrate may be performed in the inner chamber 12. The substrate may be loaded on the chuck 40 after the plasma gas 60 is removed from the inner chamber 12. The plasma gas 60 may be removed from the inner chamber 12 by the following steps. The supply of the reaction gas 22 into the inner chamber 12 is interrupted (S50). Even though the supply of the reaction gas 22 is interrupted, the plasma reaction may be still induced in the inner chamber 12. The reaction gas 22 and/or the plasma gas 60 may be gradually removed by pumping of the vacuum pump 16. The electric field 70 and/or the magnetic field 72 are removed (S60). If the power voltage applied to the field inducing units 80 and/or 90 is removed, the electric field 70 and/or the magnetic field 72 may disappear in the inner chamber 12. The plasma reaction is interrupted (S70). If the high frequency power is not supplied to the upper and lower electrodes 30 and 50, the plasma reaction may be interrupted.

Thereafter, the substrate may be loaded in the inner chamber 12 for a manufacturing process of the substrate.

As described above, the plasma equipment according to the above embodiments may include the chamber, the shower head, the upper electrode, the chuck, the lower electrode, and the field inducing unit(s). The upper and lower electrodes may be disposed in parallel to each other in the upper and lower parts or surfaces of the inner space of the chamber, respectively. The shower head and the chuck may cover the upper electrode and the lower electrode, respectively. The shower head may discharge the cleaning gas of the strong acidity into the chamber. The high frequency power applied to the upper and lower electrodes may convert the cleaning gas into the plasma gas. The field inducing unit(s) may induce the electric field or the magnetic field in the direction parallel to the upper and lower electrodes in the chamber.

The electric field or the magnetic field may concentrate the plasma gas on the inner sidewall of the chamber. The plasma gas may locally clean the inner sidewall of the chamber. Thus, the plasma equipment and the dry-cleaning method according to the aforementioned embodiments may minimize or prevent the damage of the chuck which may be caused by the strong acid plasma gas.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A plasma equipment comprising:
a chamber having an inner space;
a shower head disposed in an upper part of the inner space of the chamber, the shower head configured to discharge a cleaning gas into the chamber;
a plasma generator disposed in the inner space of the chamber, the plasma generator configured to generate a plasma gas from the cleaning gas;
a lower electrode disposed in a lower part of the inner space of the chamber;
a chuck on the lower electrode; and
a field inducing unit disposed outside the chamber, the field inducing unit configured to induce an electric field or a magnetic field within the chamber in a direction parallel to top surfaces of the chuck and the lower electrode to concentrate the plasma gas on an inner sidewall of the chamber and to protect the chuck from the plasma gas.

2. The plasma equipment of claim 1, wherein the field inducing unit includes first and second field inducing electrodes disposed opposite to each other on an outer sidewall of the chamber; and
wherein the field inducing electrodes induce the electric field in the chamber.

3. The plasma equipment of claim 2, wherein the field inducing electrodes are rotatable along the outer sidewall of the chamber and are movable up and down the outer sidewall of the chamber.

4. The plasma equipment of claim 2, wherein the chamber includes ceramic, polymer, glass, or plastic.

5. The plasma equipment of claim 1, wherein the field inducing unit includes a field inducing coil wrapped around the chamber, wherein the field inducing coil induces the magnetic field in the chamber; and
wherein the field inducing coil has a center axis extending in a direction from one side to another, opposed side of the chamber.

6. The plasma equipment of claim 5, wherein the center axis is parallel to or coincides with a direction of the magnetic field.

7. The plasma equipment of claim 6, wherein the chamber includes an inner chamber and an outer chamber surrounding the inner chamber.

8. The plasma equipment of claim 7, wherein the inner chamber and the outer chamber are configured to rotate relative to each other and to move vertically relative to each other.

9. The plasma equipment of claim 7, wherein a height of the outer chamber is two or more times greater than a height of the inner chamber.

10. The plasma equipment of claim 7, wherein the outer chamber has a hexahedral shape or a cylindrical shape.

11. The plasma equipment of claim 7, wherein the inner chamber has a cylindrical shape.

12. The plasma equipment of claim 1, wherein the plasma generator includes an upper electrode disposed in the shower head in the upper part of the inner space of the chamber.

13-15. (canceled)

16. A plasma equipment comprising:
a chamber including an inner chamber and an outer chamber, the inner chamber having an inner space, the outer chamber surrounding the inner chamber;
a shower head disposed in an upper part of the inner space of the inner chamber, the shower head configured to discharge a cleaning gas into the inner chamber;
a plasma generator disposed in the inner space of the inner chamber, the plasma generator configured to generate a plasma gas from the cleaning gas;
a lower electrode disposed in a lower part of the inner space of the inner chamber;
a chuck on the lower electrode; and
a field inducing unit disposed outside the inner chamber, the field inducing unit configured to induce an electric field and/or a magnetic field within the inner chamber in a direction parallel to top surfaces of the chuck and the lower electrode to concentrate the plasma gas on an inner sidewall of the inner chamber and to protect the chuck from the plasma gas;
wherein the inner chamber and the field inducing unit are movable relative to one another such that the plasma gas is concentrated on different areas of the inner sidewall of the inner chamber.

17. The plasma equipment of claim 16, wherein the field inducing unit includes first and second field inducing electrodes disposed opposite to each other on an outer sidewall of the inner chamber, wherein the field inducing electrodes induce the electric field in the inner chamber, and wherein:
the first and second field inducing electrodes are movable vertically together along the outer sidewall of the inner chamber; and
the first and second field inducing electrodes are rotatable together along the outer sidewall of the inner chamber.

18. The plasma equipment of claim 16, wherein the field inducing unit includes a field inducing coil helically disposed around the outer chamber, wherein the field inducing coil induces the magnetic field in the inner chamber, and wherein:
the inner chamber is rotatable within the outer chamber; and
the inner chamber is movable vertically within the outer chamber.

19. The plasma equipment of claim 16, wherein the field inducing unit includes a field inducing coil helically disposed around the outer chamber, wherein the field inducing coil induces the magnetic field in the inner chamber, and wherein:
the outer chamber is rotatable about the inner chamber; and
the inner and outer chambers are movable vertically relative to one another.

20. The plasma equipment of claim 16, wherein the field inducing unit comprises:
first and second field inducing electrodes disposed opposite to each other on an outer sidewall of the inner chamber, wherein the field inducing electrodes induce the electric field in the inner chamber; and
a field inducing coil disposed around the outer chamber, wherein the field inducing coil induces the magnetic field in the inner chamber.
